(19) United States
(12) Patent Application Publication
(10) Pub. No.: US 2007/0004172 A1
(43) Pub. Date: Jan. 4, 2007

(54) METHOD OF THINNING A WAFER

(76) Inventor: Chen-Hsiung Yang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/163,505

(22) Filed: Oct. 20, 2005

(30) Foreign Application Priority Data
Jul. 1, 2005 (TW) 094122412

(51) Int. Cl. H01L 21/46

(52) U.S. Cl. 438/458; 438/459

(57) ABSTRACT

A method of thinning a wafer. A wafer having a front surface and a back surface is provided. Subsequently, a carrier wafer is provided, and the back surface of the wafer is bonded to the carrier wafer with a bonding medium. Following that, a wafer thinning process is performed to thin the wafer from the front surface. Finally, the bonding medium is removed so as to separate the wafer from the carrier wafer.

### BACKGROUND OF THE INVENTION

1. Field of the Invention

The present invention relates to a method of thinning a wafer, and more particularly, to a method capable of reducing the wafer thickness to less than 100 micrometers by bonding the wafer to a carrier wafer with a removable bonding medium prior to performing a wafer thinning process.

2. Description of the Prior Art

In semiconductor or MEMS device fabrications, the wafer must be thinned to a proper thickness in view of functional or size considerations. The prior art wafer thinning process is mostly a polishing process or an etching process. For either one of the conventional wafer thinning method, the thickness limitation is approximately 100 micrometers. Normally, the conventional wafer thinning process can be performed before devices are fabricated, or the wafer thinning process can be performed from the back surface of the wafer after devices are fabricated. For the former condition, if the wafer thickness is less than 100 micrometers (generally referred to as ultra-thin wafer), the wafer is easy to break in delivery. For the latter condition, not only the wafer may be broken in delivery, but also the devices may be damaged in the polishing process due to stress issue or in a clean process after the etching process.

### SUMMARY OF THE INVENTION

It is therefore one object of the claimed invention to provide a method of thinning a wafer to improve the limitation of wafer thinning process.

According to the claimed invention, a method of thinning a wafer is provided. The method of thinning a wafer includes:

providing a wafer having a front surface and a back surface;

providing a carrier wafer;

bonding the back surface of the wafer to the carrier wafer with a bonding medium;

performing a wafer thinning process to thin the wafer from the front surface; and

removing the bonding medium to separate the wafer from the carrier wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 are schematic diagrams illustrating a method of thinning a wafer in accordance with a preferred embodiment of the present invention.

### DETAILED DESCRIPTION

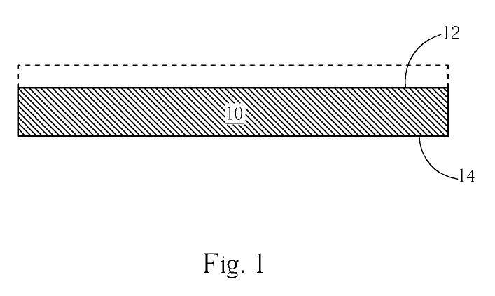

With reference to FIGS. 1-5, FIGS. 1-5 are schematic diagrams illustrating a method of thinning a wafer in accordance with a preferred embodiment of the present invention. As shown in FIG. 1, a wafer 10 having a front surface 12 and a back surface 14 is provided. A primary wafer thinning process is then performed from e.g. the front surface 12 to thin the wafer 10. In FIG. 1, the dotted line marks the original thickness of the wafer 10, and the thickness of the wafer 10 is reduced to a thickness of e.g. 100 to 150 micrometers so that the wafer 10 can be fastened and delivered safely by a standard apparatus. The primary wafer thinning process can be any current thinning process such as a polishing process, a CMP, an etching process, etc.

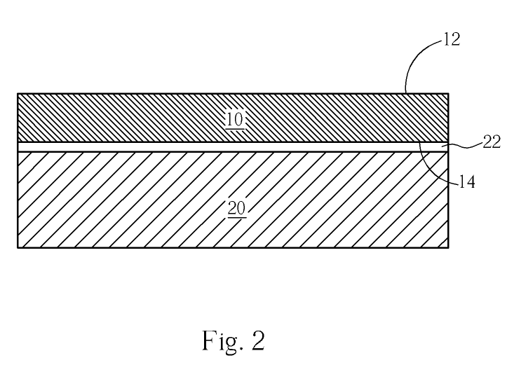

As shown in FIG. 2, a carrier wafer 20 is provided, and the back surface 14 of the wafer 10 is adhered to the carrier wafer 20 with a bonding medium 22. The carrier wafer 20 and the wafer 10 have a substantially equal size so that they can be delivered by any standard apparatus. The material of the carrier wafer 20 may be semiconductor materials, glass, quartz, ceramics, etc. In addition, the bonding medium 22 is used to adhere the wafer 10 and the carrier wafer 20, and will be removed later. Thus, the bonding medium 22 must be easy to remove. In this embodiment, the bonding medium 22 is a thermal release tape. The thermal release tape loses its stickiness when temperature is higher than its release temperature, and therefore can be removed easily without causing damages to the wafer 10. The bonding medium 22 is not limited to a thermal release tape, and may be other materials such as an UV tape, a photoresist, wax, a blue tape, etc.

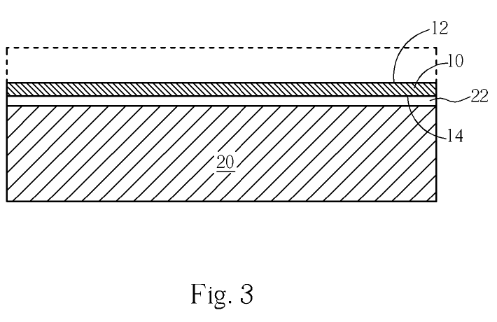

As shown in FIG. 3, a wafer thinning process is performed to reduce the thickness of the wafer 10 from the front surface 12. In FIG. 3, the dotted line marks the thickness of the wafer 10 before the wafer thinning process. The wafer thinning process may be a polishing process, a CMP process, a wet etching process or a dry etching process, and a dry etching process is preferred. In this embodiment, the wafer thinning process is a plasma etching process. Since the plasma etching process is a dry process, no further clean and baking processes are required. Consequently, the risk of damaging the wafer 10 and particle issue are diminished. After the wafer thinning process, the thickness of the wafer 10 can be reduced to less than 100 micrometers, even to approximately 10 micrometers. Since the wafer 10 is fastened to the carrier wafer 20 with the bonding medium 22, the wafer 10 can be delivered safely.

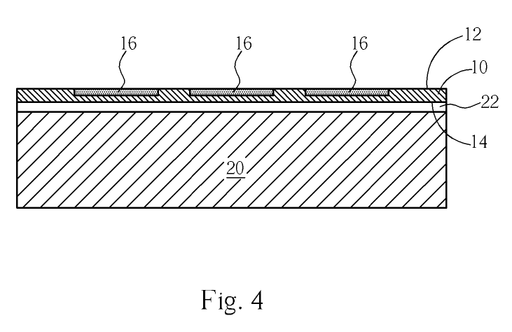

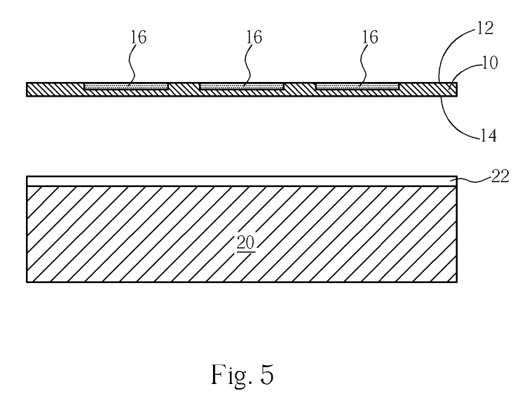

As shown in FIG. 4, devices 16 are then fabricated on the front surface 12 of the wafer 10. The devices 16 may be semiconductor devices or MEMS devices, and the method of forming the devices 16 is not redundantly described here. As shown in FIG. 5, the bonding medium 22 is removed to separate the wafer 10 from the carrier wafer 20. As previously described, the bonding medium 22 is a thermal release tape in this embodiment, and therefore can be removed easily by heating. If the bonding medium 22 is selected from other materials such as an UV tape, an UV irradiation can be performed to separate the wafer 10 and the carrier wafer 20.

In the above embodiment, the wafer is separated from the carrier wafer right after the devices are formed. However, the method of the present invention is not limited in this embodiment. For example, if the bonding medium is extendable such as using a blue tape, segment process can be incorporated into the method before the wafer and the carrier wafer are separated. In such a case, an automatic wafer expansion process can be further integrated.

In conclusion, the method of the present invention fixes the wafer to a carrier wafer with a bonding medium, and performs a wafer thinning process to reduce the thickness of the wafer. Under such a condition, the wafer is well fastened and supported. Therefore, the method of the present invention can dramatically improve the limitation of wafer thinning process, and prevent stress and wafer warp issues.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of thinning a wafer comprising:
providing a wafer having a front surface and a back surface;
providing a carrier wafer;
bonding the back surface of the wafer to the carrier wafer with a bonding medium;
performing a wafer thinning process to thin the wafer from the front surface; and
removing the bonding medium to separate the wafer from the carrier wafer.

2. The method of claim 1, wherein the bonding medium comprises a thermal release tape, an UV tape, a photoresist, a wax or a blue tape.

3. The method of claim 1, wherein the wafer thinning process is a dry etching process.

4. The method of claim 3, wherein the dry etching process is a plasma etching process.

5. The method of claim 1, wherein the wafer thinning process is a wet etching process.

6. The method of claim 1, further comprising forming a plurality of devices on the front surface of the wafer subsequent to the wafer thinning process.

7. The method of claim 1, further comprising performing a primary wafer thinning process prior to bonding the wafer to the carrier wafer.

8. The method of claim 7, wherein the wafer has a thickness of greater than 100 micrometers after the primary wafer thinning process.

9. The method of claim 1, wherein the wafer has a thickness of less than 100 micrometers after the wafer thinning process.

10. The method of claim 1, wherein the carrier wafer is used to fasten and deliver the wafer.

11. A method of thinning a wafer comprising:
providing a wafer having a front surface and a back surface;
performing a primary wafer thinning process;
providing a carrier wafer;
bonding the back surface of the wafer to the carrier wafer with a bonding medium;
performing a wafer thinning process to thin the wafer from the front surface; and
removing the bonding medium to separate the wafer from the carrier wafer.

12. The method of claim 11, wherein the bonding medium comprises a thermal release tape, an UV tape, a photoresist, a wax or a blue tape.

13. The method of claim 11, wherein the wafer thinning process is a dry etching process.

14. The method of claim 13, wherein the dry etching process is a plasma etching process.

15. The method of claim 11, wherein the wafer thinning process is a wet etching process.

16. The method of claim 11, further comprising forming a plurality of devices on the front surface of the wafer subsequent to the wafer thinning process.

17. The method of claim 11, wherein the wafer has a thickness of greater than 100 micrometers after the primary wafer thinning process.

18. The method of claim 11, wherein the wafer has a thickness of less than 100 micrometers after the wafer thinning process.
